(19) United States
(12) Patent Application Publication
(10) Pub. No.: US 2016/0173038 A1
(43) Pub. Date: Jun. 16, 2016

(54) POWER AMPLIFIER

(71) Applicant: Samsung Electro-Mechanics Co., Ltd, Suwon-si (KR)

(72) Inventors: Hyeon Seok HWANG, Suwon-si (KR); Suk Chan KANG, Suwon-si (KR)

(73) Assignee: Samsung Electro-Mechanics Co., Ltd, Suwon-si (KR)

(21) Appl. No.: 14/969,840

(22) Filed: Dec. 15, 2015

(30) Foreign Application Priority Data
Dec. 16, 2014 (KR) 10-2014-0181733

(51) Int. Cl. H03F 1/02; H03F 3/19; H03F 3/21

(52) U.S. Cl. CPC H03F 1/0205; H03F 3/21; H03F 3/19; H03F 2200/451

(57) ABSTRACT

A power amplifier may include an amplifying unit, a ballast resistor, and a bypass unit. The amplifying unit includes an amplifying transistor to amplify an input signal. The ballast resistor is connected to a base of the amplifying transistor. The bypass unit is connected in parallel to the ballast resistor.

### CROSS-REFERENCE TO RELATED APPLICATION

This application claims the priority and benefit under 35 USC 119(a) of Korean Patent Application No. 10-2014-0181733 filed on Dec. 16, 2014, with the Korean Intellectual Property Office, the disclosure of which is incorporated herein by reference.

### BACKGROUND

1. Field

The following description relates to a power amplifier.

2. Description of Related Art

Wireless communications devices such as portable terminals perform wireless communications using power amplifiers.

When a power amplifier transmits high power, the power amplifier transmits the high power with respect to a desired frequency band, while amplifying a noise signal with respect to an adjacent frequency band. As a result, a degradation of reception sensitivity and errors occur during the reception of the high power.

In particular, in an amplifier including a plurality of transistors connected in parallel, when a base-emitter voltage of a specific transistor is lower than base-emitter voltages of other transistors, the majority of an operating current of a circuit concentrates only on the specific transistor, causing a current concentration (hogging) phenomenon.

In order to solve such phenomenon, a scheme of connecting a resistor to a base terminal of a transistor is employed. However, in the scheme, noise characteristics of a circuit, in particular, when high power is transmitted, are degraded.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a power amplifier, including: an amplifying unit including an amplifying transistor to amplify an input signal; a ballast resistor connected to a base of the amplifying transistor; and a bypass unit connected in parallel to the ballast resistor.

The bypass unit may activates or deactivates a bypass path that bypasses the ballast resistor according to a swing width of a gate voltage from the amplifying transistor.

The bypass unit may include a first diode including a cathode connected to a base terminal of the amplifying transistor.

The bypass unit further may include a second diode including an anode connected to the base terminal of the amplifying transistor.

The bypass unit may include a variable resistor with a variable resistance that varies according to a magnitude of the gate voltage.

The bypass unit may activate the bypass path in response to a magnitude of an absolute value of the gate voltage of the amplifying transistor being equal to or greater than a threshold voltage.

The ballast resistor may be activated in response to a magnitude of an absolute value of the gate voltage of the amplifying transistor being lower than a threshold voltage.

The bypass unit may include a first and second diodes connected in a back-to-back manner forming a bypass path, and wherein the bypass unit activates or deactivates the bypass path bypassing the ballast resistor according to a swing width of a gate voltage from the amplifying transistor.

In accordance with an embodiment, there is provided a power amplifier, including: an amplifying unit including amplifying transistors connected in parallel, ballast resistors connected to bases of the amplifying transistors; and a bypass unit including bypass elements connected to the ballast resistors in parallel.

The ballast resistors may be configured to remove influence of base-emitter voltages from the amplifying transistors on a base current, and the base current may be a current input to base terminals of the amplifying transistors.

The bypass elements may include a first diode having a cathode connected to a base terminal of the amplifying transistor.

The bypass elements may further include a second diode having an anode connected to the base terminal of the amplifying transistor.

The bypass elements may include a variable resistor having a resistance value varied according to a magnitude of a gate voltage.

The bypass unit may activate a bypass path in response to a magnitude of an absolute value of a gate voltage of the amplifying transistor being equal to or greater than a threshold voltage.

The ballast resistor may be activated in response to a magnitude of an absolute value of a gate voltage of the amplifying transistor being lower than a threshold voltage.

Other features and aspects will be apparent from the following detailed description, the drawings, and the claims.

### BRIEF DESCRIPTION OF DRAWINGS

These and/or other aspects will become apparent and more readily appreciated from the following description of the embodiments, taken in conjunction with the accompanying drawings in which:

FIG. 1 is a view illustrating a configuration of a power amplifier, according to an embodiment;

FIG. 2 is a circuit diagram illustrating an embodiment of a power amplifier;

FIG. 3 is a circuit diagram illustrating another embodiment of a power amplifier;

FIG. 4 is a circuit diagram illustrating another embodiment of a power amplifier;

FIG. 5A through 5C are circuit diagrams illustrating another embodiment of a power amplifier;

FIG. 6 is a graph illustrating characteristics of a diode;

FIG. 7 is a graph illustrating a comparison between gain characteristics of a power amplifier, according to an embodiment, and a conventional power amplifier; and

FIGS. 8A through 11B are graphs illustrating RX noise of a power amplifier, according to an embodiment, over input power.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

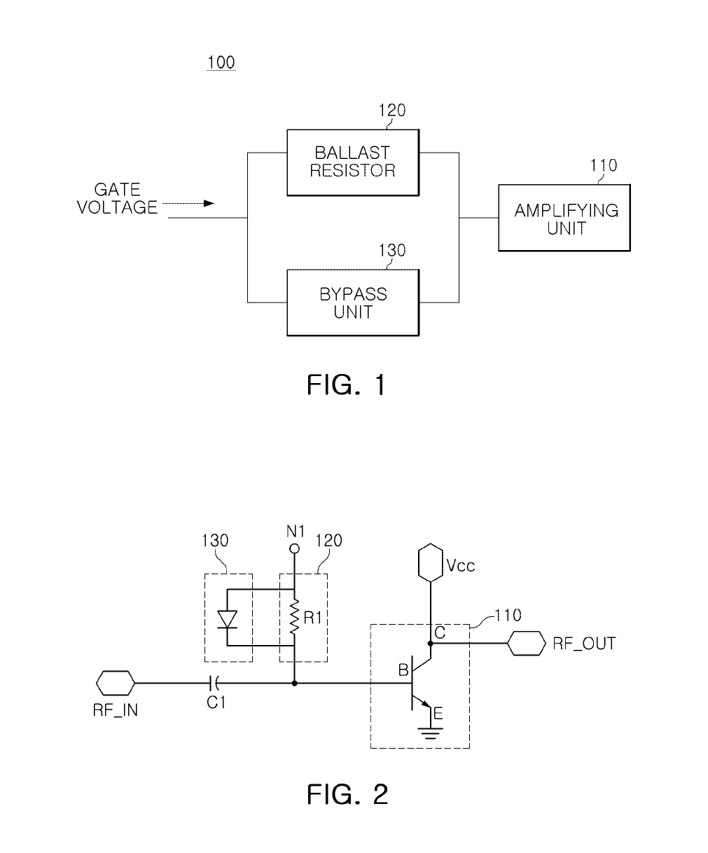

FIG. 1 is a view illustrating a configuration of a power amplifier, according to an embodiment.

Referring to FIG. 1, a power amplifier 100 includes an amplifying unit 110, a ballast resistor 120, and a bypass unit 130.

The amplifying unit 110 includes an amplifying transistor amplifying an input signal. According to an embodiment, the amplifying unit 110 includes one or a plurality of amplifying transistors.

The ballast resistor 120 is connected to a base terminal of the amplifying transistor of the amplifying unit 110. The ballast resistor 120 removes an influence of a base-emitter voltage of the amplifying transistor in the amplifying unit 110 on a base current. In an example, the base current refers to a current input to a base terminal of the amplifying transistor.

The bypass unit 130 is connected to the ballast resistor 120 in parallel. The bypass unit 130 activates or deactivates a bypass path, bypassing the ballast resistor 120, depending on a magnitude of a voltage input to the base terminal of the amplifying transistor.

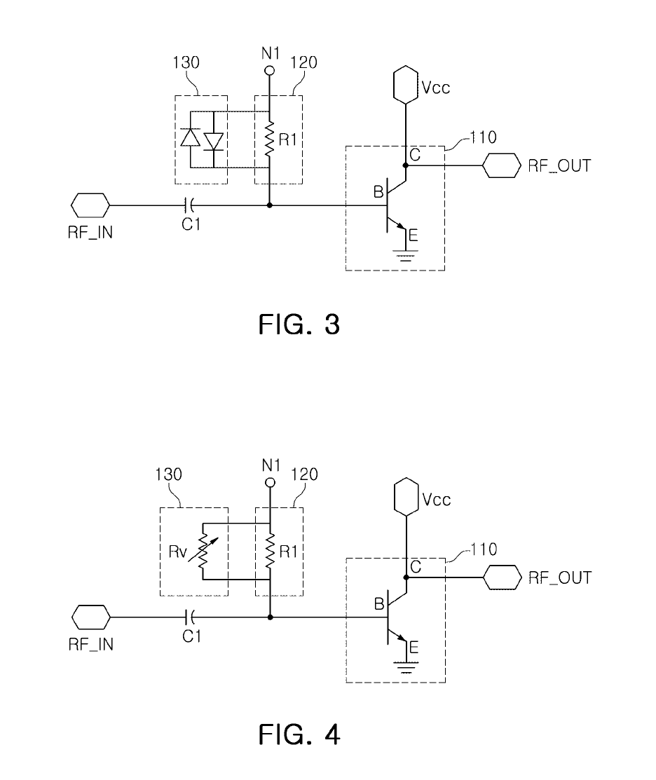

Hereinafter, various embodiments of the power amplifier 100 will be described with reference to FIGS. 2 through 5.

FIG. 2 is a circuit diagram illustrating an embodiment of a power amplifier.

Referring to FIG. 2, the amplifying unit 110 includes an amplifying transistor, and the ballast resistor 120 and the bypass unit 130 are connected to a base terminal of the amplifying transistor. The ballast resistor 120 and the bypass unit 130 are connected in parallel.

The ballast resistor 120 removes an influence generated due to a base-emitter voltage of the amplifying transistor 110. That is, when the ballast resistor is not present, a base current fluctuates due to the base-emitter voltage of the amplifying transistor 110, and thus, the ballast resistor 120 prevents such fluctuations in the base current.

The ballast resistor 120 affects noise characteristics. Thus, in an embodiment, the ballast resistor 120 is selectively activated using the bypass unit 130.

The bypass unit 130 activates and deactivates a bypass path, bypassing the ballast resistor 120, depending on a swing width of a gate voltage of the amplifying transistor 100.

As illustrated in FIG. 2, the bypass unit 130 is formed using a single diode. However, a person of relevant skill in the art will appreciates that multiple diodes may be used to include the structural configuration and perform the functions of the single diode illustrated in FIG. 2.

Referring to FIG. 2, the bypass unit 130 includes a first diode having a cathode connected to a base terminal of the amplifying transistor 110.

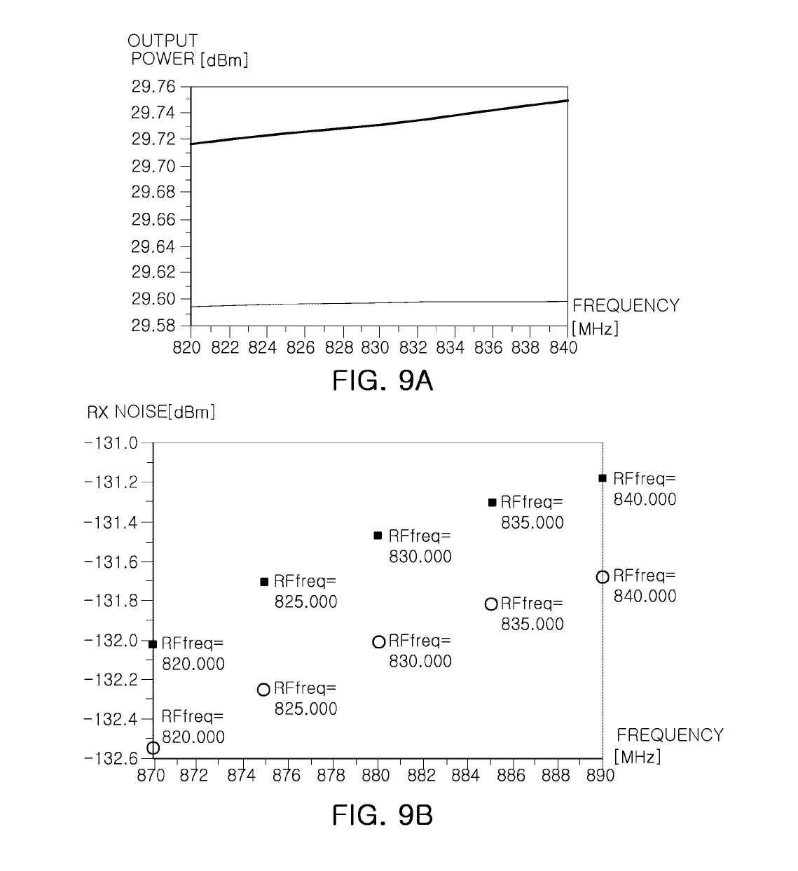

FIG. 6 is a graph illustrating characteristics of a diode. Referring to FIG. 6, the graph illustrates the diode having properties of a high resistor when a threshold voltage is lower than Vd, and having properties of a low resistance value when the threshold voltage is equal to or higher than Vd.

Thus, the bypass unit 130 of FIG. 2 activates or deactivates a bypass path using the first and second diodes connected in a back-to-back manner.

Because the bypass unit 130 includes the first and the second diodes connected in the back-to-back manner, even when an input gate voltage has an alternating current (AC) waveform, the bypass unit 130 forms a bypass path. Thus, the bypass unit 130 activates or deactivates the bypass path bypassing the ballast resistor 120 according to a swing width of a gate voltage having an AC waveform.

In an embodiment, when a magnitude of an absolute value of a gate voltage of the amplifying transistor 110 is equal to or greater than a threshold voltage, the bypass unit 130 activates the bypass path formed by the first and second diodes. Thus, because a base current is applied using the bypass path formed by the first and second diodes, the base current does not flow through or detours from the ballast resistor 120.

Thus, the ballast resistor 120 is activated when the magnitude of the absolute value of the gate voltage of the amplifying transistor 110 is lower than the threshold voltage.

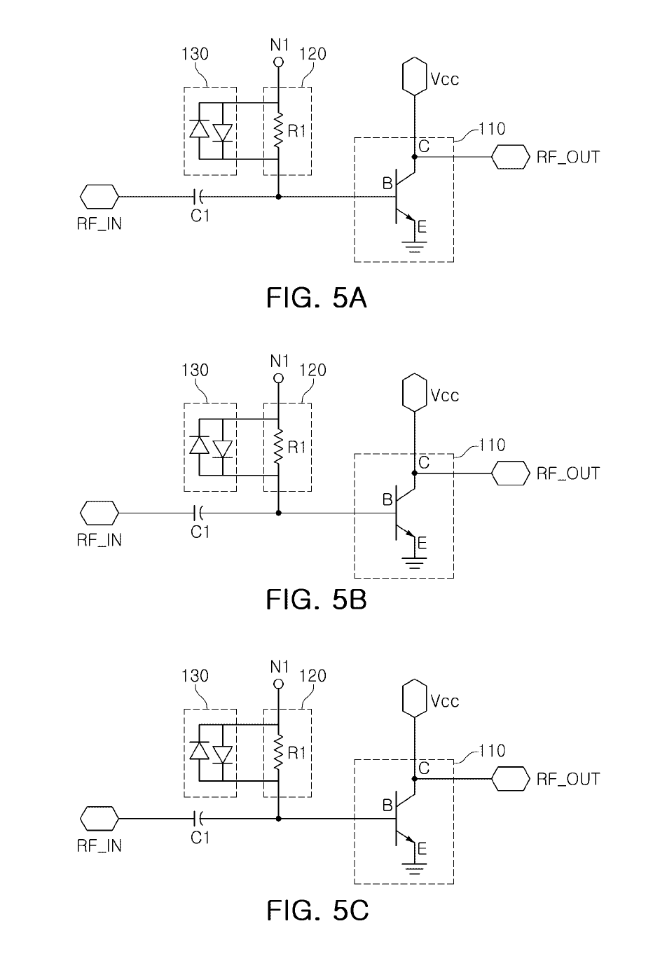

FIG. 3 is a circuit diagram illustrating another embodiment of a power amplifier.

In another embodiment of the power amplifier illustrated in FIG. 3, a bypass unit 130 includes a pair of diodes connected in a back-to-back manner. For example, the bypass unit 130 includes a first diode having a cathode connected to a base terminal of the amplifying transistor 110 and a second diode having an anode connected to the base terminal.

The first diode is activated or deactivated as a bypass path, according to a magnitude of a gate voltage flowing to the base terminal. In one example, the gate voltage has a direct current (DC) waveform.

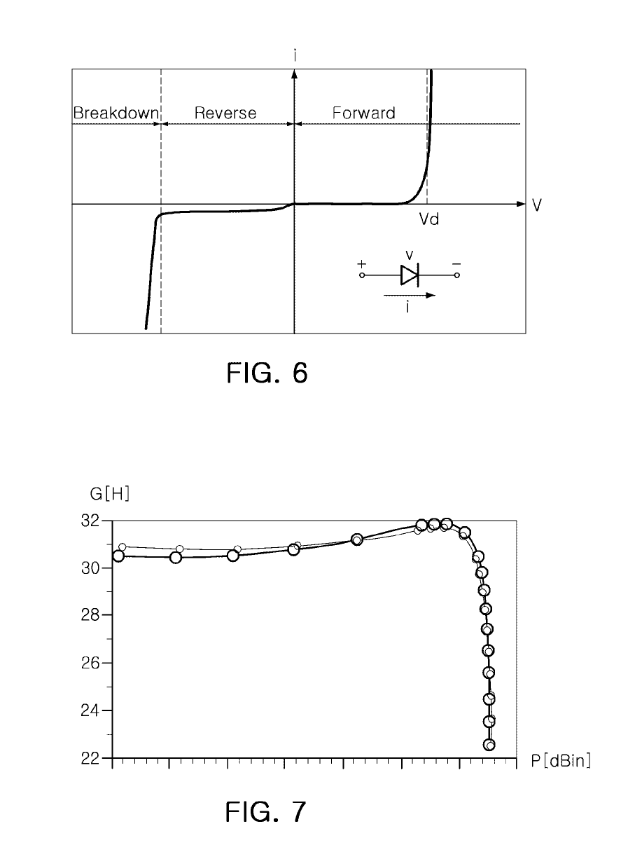

FIG. 4 is a circuit diagram illustrating another embodiment of a power amplifier.

In another embodiment of the power amplifier illustrated in FIG. 4, a bypass unit 130 is configured using a variable resistor.

Referring to FIG. 4, the bypass unit 130 includes a variable resistor Rv having a resistance value varied according to a magnitude of a gate voltage.

Although not shown, in an embodiment, the power amplifier may further include a variable control circuit varying a resistance value of the variable resistor Rv. The variable control circuit controls the variable resistor Rv to vary a resistance value of the variable resistor Rv according to a magnitude of a gate voltage.

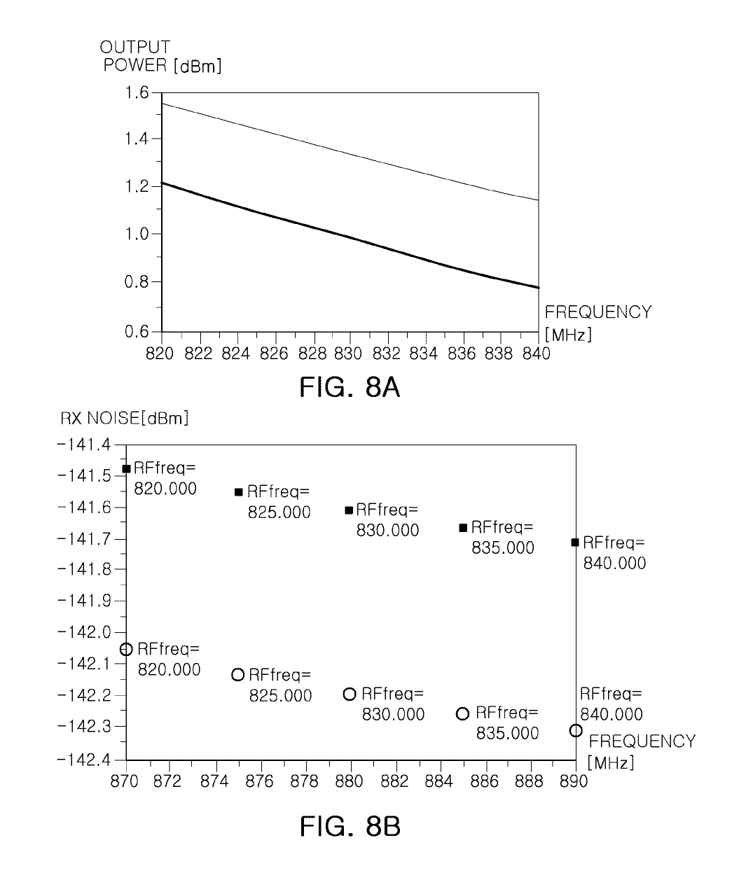

FIG. 5A through 5C are circuit diagrams illustrating another embodiment of a power amplifier.

The power amplifier, according to the embodiments illustrated in FIG. 5A through 5C, includes a plurality of amplifying transistors. In the embodiment illustrated in FIG. 5A through 5C, a bypass unit 130 is configured using diodes connected in a back-to-back manner, similar to the embodiment illustrated in FIG. 2, but the configuration is merely illustrative. The bypass unit 130 of FIG. 5A through 5C may be configured as illustrated in FIG. 3 or 4, in alternative embodiments.

Referring to FIG. 5A through 5C, the amplifying unit includes a plurality of amplifying transistors connected in parallel.

The plurality of ballast resistors 120 are connected to base terminals of the plurality of amplifying transistors, respectively. Each of the plurality of ballast resistors 120 remove an influence of a base-emitter voltage of each of the amplifying transistors on a base current. In an example, the base current is a current input to a base terminal of each of the amplifying transistors.

The bypass unit 130 includes a plurality of bypass elements connected to the plurality of ballast resistors, respectively, in parallel.

In an embodiment, each of the bypass elements includes a first diode having a cathode connected to a base terminal of each of the amplifying transistors. In an alternative embodiment, some of the bypass elements include a first diode having a cathode connected to a base terminal of each of the amplifying transistors. In another embodiment, each of the bypass elements includes a first diode having a cathode connected to a base terminal of each of the amplifying transistors and a second diode having an anode connected to the base terminal of each of the amplifying transistors.

In another embodiment, each of the bypass elements includes a variable resistor having a resistance value varied according to a magnitude of a gate voltage. As described above, the power amplifier further includes a variable control circuit controlling the variable resistor.

The bypass unit 130 activates a bypass path when a magnitude of an absolute value of a gate voltage of the amplifying transistor is equal to or greater than a threshold voltage.

Each of the ballast resistors 120 is activated when the magnitude of the absolute value of the gate voltage of each of the amplifying transistors is lower than a threshold voltage.

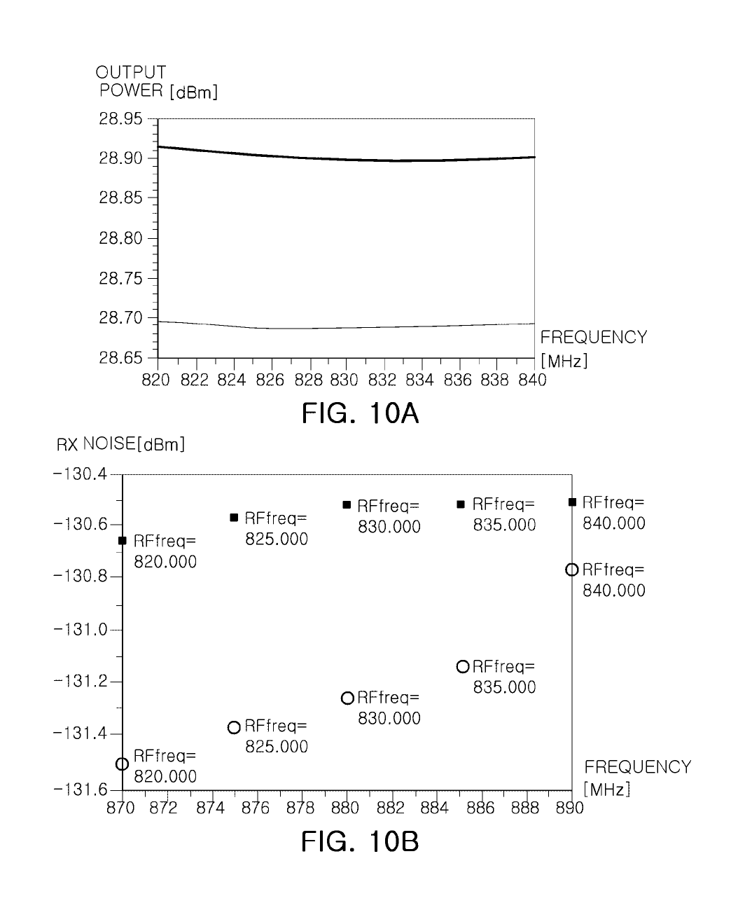

FIG. 7 is a graph illustrating a comparison between gain characteristics of a power amplifier, according to an embodiment and the related art power amplifier.

In FIG. 7, a thick solid line represents gain characteristics, according to an embodiment. A thin solid line represents gain characteristics of the related art without a bypass unit.

As illustrated, an addition of the bypass unit obtains an effect of reducing a gain in small or low power and increasing the gain in large or great power. Such a change does not cause a significant change in an overall performance of the power amplifier.

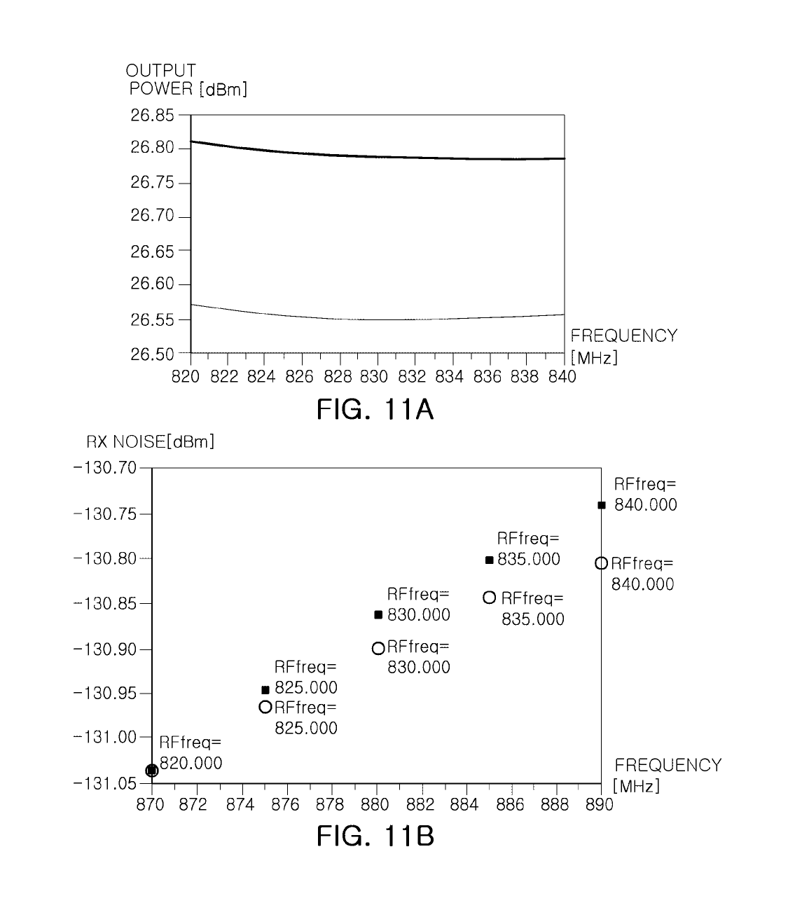

FIGS. 8A through 11B are graphs illustrating RX noise of a power amplifier, according to an embodiment, over input power.

FIGS. 8A and 8B illustrate an example in which input power is −30 dBm, FIGS. 9A and 9B illustrate an example in which input power is −2 dBm, FIGS. 10A and 10B illustrate an example in which input power is −3 dBm, and FIGS. 11A and 11B illustrate an example in which input power is −5 dBm.

In FIGS. 8A through 11B, thick solid lines and circles represent the power amplifier, in accordance with an embodiment, and thin sold lines and quadrangles represent a conventional scheme without a bypass unit. Also, the X axis is frequency and the Y axis is RX noise.

As illustrated in FIGS. 8A and 8B, when input power is −30 dBm, output power of the power amplifier, in accordance with an embodiment, is about 0.4 dBm lower than a conventional scheme, while Rx noise is significantly reduced.

In FIGS. 9A through 11B, in accordance with an embodiment, the power amplifier has higher output power and lower noise over the same input power.

As set forth above, according to various embodiments, noise caused when high power is transferred is effectively reduced, while a current concentration phenomenon is prevented.

The apparatuses, units, modules, devices, and other components illustrated in FIGS. 1-5C that perform the operations described herein with respect to FIGS. 1-5C are implemented by hardware components. Examples of hardware components include processors, controllers, sensors, generators, drivers, and any other electronic components known to one of ordinary skill in the art.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power amplifier, comprising:
an amplifying unit comprising an amplifying transistor to amplify an input signal;
a ballast resistor connected to a base of the amplifying transistor; and
a bypass unit connected in parallel to the ballast resistor.

2. The power amplifier of claim 1, wherein the bypass unit activates or deactivates a bypass path that bypasses the ballast resistor according to a swing width of a gate voltage from the amplifying transistor.

3. The power amplifier of claim 1, wherein the bypass unit comprises a first diode comprising a cathode connected to a base terminal of the amplifying transistor.

4. The power amplifier of claim 3, wherein the bypass unit further comprises a second diode comprising an anode connected to the base terminal of the amplifying transistor.

5. The power amplifier of claim 2, wherein the bypass unit comprises a variable resistor with a variable resistance that varies according to a magnitude of the gate voltage.

6. The power amplifier of claim 2, wherein the bypass unit activates the bypass path in response to a magnitude of an absolute value of the gate voltage of the amplifying transistor being equal to or greater than a threshold voltage.

7. The power amplifier of claim 2, wherein the ballast resistor is activated in response to a magnitude of an absolute value of the gate voltage of the amplifying transistor being lower than a threshold voltage.

8. The power amplifier of claim 1, wherein the bypass unit comprises a first and second diodes connected in a back-to-back manner forming a bypass path, and wherein the bypass unit activates or deactivates the bypass path bypassing the ballast resistor according to a swing width of a gate voltage from the amplifying transistor.

9. A power amplifier, comprising:
an amplifying unit comprising amplifying transistors connected in parallel,
ballast resistors connected to bases of the amplifying transistors; and
a bypass unit comprising bypass elements connected to the ballast resistors in parallel.

10. The power amplifier of claim 9, wherein
the ballast resistors are configured to remove influence of base-emitter voltages from the amplifying transistors on a base current, and
the base current is a current input to base terminals of the amplifying transistors.

11. The power amplifier of claim 9, wherein the bypass elements comprise a first diode having a cathode connected to a base terminal of the amplifying transistor.

12. The power amplifier of claim 11, wherein the bypass elements further comprise a second diode having an anode connected to the base terminal of the amplifying transistor.

13. The power amplifier of claim 9, wherein the bypass elements comprise a variable resistor having a resistance value varied according to a magnitude of a gate voltage.

14. The power amplifier of claim 9, wherein the bypass unit activates a bypass path in response to a magnitude of an absolute value of a gate voltage of the amplifying transistor being equal to or greater than a threshold voltage.

15. The power amplifier of claim 8, wherein the ballast resistor is activated in response to a magnitude of an absolute value of a gate voltage of the amplifying transistor being lower than a threshold voltage.
